(19) United States
(12) Patent Application Publication
(10) Pub. No.: US 2025/0160180 A1
(43) Pub. Date: May 15, 2025

(54) HIGH-BRIGHTNESS OLED DISPLAY DEVICE, PREPARATION METHOD THEREOF AND DISPLAY APPARATUS

(71) Applicant: SEMICONDUCTOR INTEGRATED DISPLAY TECHNOLOGY CO., LTD., Anhui Province (CN)

(72) Inventors: Jingwen TIAN, Beijing (CN); Shengfang LIU, Beijing (CN); Weiwei LI, Beijing (CN); Xiaojia LIU, Beijing (CN); Zhengtao ZHAO, Beijing (CN); Zhengxiao ZHAO, Beijing (CN)

(21) Appl. No.: 18/771,082

(22) Filed: Jul. 12, 2024

(30) Foreign Application Priority Data
Nov. 15, 2023 (CN) 202311521739.2

(51) Int. Cl. H10K 59/80; H10K 50/856; H10K 71/60

(52) U.S. Cl. CPC H10K 59/876; H10K 50/856; H10K 59/80518; H10K 71/60

(57) ABSTRACT

Provided are a high-brightness OLED display device, a preparation method thereof and a display apparatus, which relates to the technical field of OLED display. The high-brightness OLED display device includes a substrate and an optical microcavity structure on the substrate, the optical microcavity structure includes an R optical microcavity area, a G optical microcavity area and a B optical microcavity area. A cavity length of the G optical microcavity area is greater than that of the B optical microcavity region and is smaller than that of the R optical microcavity area. The beneficial effects of the disclosure are that RGB pixels can independently emit corresponding spectrums without the help of CF, realizing colorization control of silicon-based products, improving light extraction efficiency and product yield.

### CROSS-REFERENCE TO RELATED APPLICATIONS

The disclosure claims priority to Chinese Patent Application No. 202311521739.2, filed on Nov. 15, 2023, which is hereby incorporated by reference in its entirety.

### TECHNICAL FIELD

The disclosure relates to the technical field of OLED display, and in particular to a high-brightness OLED display device, preparation method thereof and display apparatus.

### BACKGROUND

OLED colorization technologies mainly include three methods of RGB-SBS (RGB pixel juxtaposition method, Side-By-Side), W+CF (Color Filter method, also called “White light+Color Filter” method) and CCM (Color Conversion Method). At present, most silicon-based OLED full-color products use the first two methods.

When silicon-based OLED full-color products adopt WOLED (White light OLED) plus CF (Color Filter) technology, evaporating a film layer on the entire surface using a CMM (Common Metal Mask) can achieve 2000 PPI to 3000 PPI. The disadvantage is that an optical microcavity in an evaporation section cannot be independently controlled, and a color film process must be used to realize RGB light emission, resulting in light emission loss of about 70%. When the brightness of the products is greater than 5000 nit, product requirements cannot be met.

When silicon-based OLED full-color products adopt an RGB-SBS process route, independent microcavity control for R, G, and B light emitting materials can be achieved, so that the overall OLED device performance (efficiency, life, etc.) can be optimized. Evaporating a film layer using a metal mask FMM (Fine Metal Mask) can achieve 2000 PPI to 3000 PPI. However, a single pixel opening on the metal mask FMM is only 6 μm to 10 μm, and a PDL Gap is only 2 μm to 4 μm, therefore, a hole blocking problem may occur after an FMM is evaporated for about ten times. At the same time, a conventional RGB-SBS process route evaporation requires 6 FMM operations, and the product yield is lower.

Therefore, the current silicon-based OLED full-color products have the following problems: 1) in the W+CF process, a WOLED device cannot independently emit spectrum because RGB light emitting layers emit light at the same time, a CF (Color Filter) needs to be used to achieve RGB independent light emission and color control, which leads to a larger light emission loss and a lower light emission efficiency; 2) in the RGB-SBS process, when silicon-based products achieve high brightness, due to the small single pixel opening, a hole blocking problem may occur after an FMM is evaporated for about ten times, and the product yield is lower.

For example, the related art discloses a white light OLED display and a packaging method thereof. The white light OLED display includes: a glass cover plate, a color filter layer coated on the glass cover plate; a transparent protective layer covering the color filter layer; a desiccant layer on the transparent protective layer; and a TFT substrate including a white light OLED layer; the color filter layer, the transparent protective layer and the desiccant layer sandwiched between the glass cover plate and the TFT substrate including the white light OLED layer. The OLED display still cannot independently emit spectrum because RGB light emitting layers emit light at the same time, and a CF (color filter) needs to be used to achieve RGB independent light emission, leading to a larger light emission loss and a lower light emission efficiency, which cannot solve the problems mentioned in the disclosure.

### SUMMARY

In order to solve the above technical problems, the disclosure provides a high-brightness OLED display device, a preparation method thereof, and a display apparatus, so that RGB pixels can independently emit corresponding spectrum without using CF, realizing color control of silicon-based products and improving light emission efficiency.

In order to achieve the above object, a technical solution adopted by the disclosure to solve the technical problems includes: a high-brightness OLED display device including a substrate; and an optical microcavity structure on the substrate; where the optical microcavity structure includes an R optical microcavity area, a G optical microcavity area and a B optical microcavity area, and a cavity length of the G optical microcavity area is greater than a cavity length of the B optical microcavity area and smaller than a cavity length of the R optical microcavity area.

The optical microcavity structure includes: an anode layer with a total reflection function, an organic layer on the anode layer, and a cathode layer with a semi-reflective and semi-transparent function.

The anode layer includes an R-anode, a G-anode and a B-anode, the organic layer includes an organic layer I, an organic layer II and an organic layer III, and the cathode layer includes an R-cathode, a G-cathode and a B-cathode; the R optical microcavity area includes the R-anode, the organic layer I on the R-anode, and the R-cathode, the G optical microcavity area includes the G-anode, the organic layer II on the G-anode, and the G-cathode, and the B optical microcavity area includes the B-anode, the organic layer III on the B-anode, and the B-cathode.

The cavity length of the R optical microcavity area is a sum of thicknesses of respective film layers in the R optical microcavity area, the cavity length of the G optical microcavity area is a sum of thicknesses of respective film layers in the G optical microcavity area, the cavity length of the B optical microcavity area is a sum of thicknesses of respective film layers in the B optical microcavity area, and the thickness of each film layer satisfies a formula of:

$$\sum {n}_{i} {d}_{i} + \frac{∅}{4 Π} λ = m \times \frac{λ}{2} ;$$

where nᵢ is a refractive index of each film layer, dᵢ is a thickness of each film layer, Ø is a phase shift of light reflection on surfaces of the cathode layer and anode layer, γ is a wavelength value at a highest value of a spectrum, m is a positive integer, is an order of a microcavity.

The organic layer I and the organic layer II have the same structure, and a thickness of the R-anode is greater than a thickness of the G-anode.

The thickness of the G-anode is equal to a thickness of the B-anode, and a thickness of the organic layer I or a thickness of the organic layer II is greater than a thickness of the organic layer III.

A microcavity thickness compensation layer is provided in both the organic layer I and the organic layer II, and the microcavity thickness compensation layer includes an R light emitting layer and/or a G light emitting layer, and a thickness of the R light emitting layer and a thickness of the G light emitting layer are both set to a range of 10 nm to 80 nm.

The thickness of the B-anode and the thickness of the G-anode are both set to a range of 5 nm to 80 nm, and a thickness of the R-anode is set to a range of 50 nm to 200 nm.

The organic layer includes an OLED device unit I, an OLED device unit II and a charge generation layer (CGL) connected between the OLED device unit I and OLED device unit II, the OLED device unit I is connected to the anode layer, and the OLED device unit II is connected to the cathode layer.

The OLED device unit I includes a light emitting layer I, and one side of the light emitting layer I is connected to the anode layer through an electron blocking layer I, a hole transport layer I and a hole injection layer in sequence, and the other side of the light emitting layer I is connected to the CGL layer through a hole blocking layer I and an electron transport layer I in sequence; the OLED device unit II includes a light emitting layer II, and one side of the light emitting layer II is connected to the CGL layer through an electron blocking layer II and a hole transport layer II in sequence, and the other side of the light emitting layer II is connected to the cathode layer through a hole blocking layer II, an electron transport layer II, and an electron injection layer in sequence.

The light emitting layer I includes an R light emitting layer and a B light emitting layer I arranged in sequence from bottom to top, the R light emitting layer covers the R-anode and G-anode, the B light emitting layer I covers the anode layer; the light emitting layer II includes a G light emitting layer and a B light emitting layer II arranged in sequence from bottom to top, the G light emitting layer covers the R-anode and the G-anode, and the B light emitting layer II covers the anode layer.

The light emitting layer I includes a G light emitting layer and a B light emitting layer I arranged in sequence from bottom to top, the G light emitting layer covers the R-anode and G-anode, the B light emitting layer I covers the anode layer; the light emitting layer II includes an R light emitting layer and a B light emitting layer II arranged in sequence from bottom to top, the R light emitting layer covers the R-anode and the G-anode, and the B light emitting layer II covers the anode layer.

The light emitting layer I includes an R light emitting layer covering the anode layer, the light emitting layer II includes a G light emitting layer and a B light emitting layer II arranged in sequence from bottom to top, the G light emitting layer covers the R-anode and the G-anode, and the B light emitting layer II covers the anode layer.

The light emitting layer I includes a G light emitting layer covering the anode layer, the light emitting layer II includes an R light emitting layer and a B light emitting layer II arranged in sequence from bottom to top, the R light emitting layer covers the R-anode and the G-anode, and the B light emitting layer II covers the anode layer.

The light emitting layer I includes a G light emitting layer and a B light emitting layer I arranged in sequence from bottom to top, the G light emitting layer covers the R-anode and the G-anode, and the B light emitting layer I covers the anode layer; the light emitting layer II includes an R light emitting layer covering the anode layer.

The light emitting layer I includes an R light emitting layer and a B light emitting layer I arranged in sequence from bottom to top, the R light emitting layer covers the R-anode and the G-anode, and the B light emitting layer I covers the anode layer; the light emitting layer II includes a G light emitting layer covering the anode layer.

The optical microcavity structure is connected to an encapsulation layer through a capping layer (CPL).

A high-brightness OLED display apparatus includes the OLED display device.

A method for preparing a high-brightness OLED display device includes:
step 1: preparing an anode layer including an R-anode, a G-anode and a B-anode on the substrate, where a thickness of the R-anode is greater than a thickness of the G-anode and a thickness of the B-anode;
step 2: stacking and preparing an organic layer on the anode layer, including preparing a B light emitting layer covering the anode layer using a common metal mask (CMM) and preparing an R light emitting layer and/or a G light emitting layer covering the R-anode and G-anode using a fine metal mask (FMM);
step 3: preparing a cathode layer, a capping layer (CPL) and an encapsulation layer on the organic layer in sequence.

Beneficial effects of the disclosure are as follows.

1. In the disclosure, optical microcavity areas with different cavity lengths are set at corresponding positions of R, G, and B pixels on the substrate, and the cavity length of the G optical microcavity area is greater than the cavity length of the B optical microcavity area and smaller than the cavity length of the R optical microcavity area. By changing the cavity length of the corresponding optical microcavity area, R, G, and B pixels in the OLED display device have corresponding microcavity optical path lengths, respectively, so that the RGB pixels can independently emit corresponding spectrum without using the CF, realizing color control of silicon-based products and improving light emission efficiency.

2. In the disclosure, the optical microcavity structure includes an anode layer, an organic layer on the anode layer and a cathode layer. By adjusting the thickness of the corresponding R-anode, G-anode and B-anode on the anode layer, and combining with organic layers of different thicknesses, the cavity length of the corresponding optical microcavity area is adjusted; the thickness of the R-anode is greater than the thickness of the G-anode and the thickness of the B-anode, the R-anode and G-anode are covered with the R light emitting layer and/or the G light emitting layer, the R light emitting layer and the G light emitting layer are prepared using the FMM mask, and the openings of the FMM mask are RG pixels, increasing an aperture ratio of the FMM mask and improving service life of the FMM mask. The entire process at most uses two times of the FMM mask to achieve RGB independent light emission, avoiding hole blocking problems due to evaporating the same position by using different film layer masks, and improving product yield.

### BRIEF DESCRIPTION OF FIGURES

The following is brief description of contents illustrated in each of drawings in the description of the disclosure and marks in the drawings.

FIG. 1 is a schematic structural diagram of Embodiment 1 of a high-brightness OLED display device according to the disclosure.

FIG. 2 is a schematic structural diagram of Embodiment 2 of a high-brightness OLED display device according to the disclosure.

FIG. 3 is a RGB pixel spectrum diagram of the OLED display devices of Embodiment 1 and Embodiment 2 of the disclosure.

FIG. 4 is a schematic structural diagram of Embodiment 3 of a high-brightness OLED display device of the disclosure.

FIG. 5 is a schematic structural diagram of Embodiment 4 of a high-brightness OLED display device of the disclosure.

FIG. 6 is a schematic structural diagram of Embodiment 5 of a high-brightness OLED display device of the disclosure.

FIG. 7 is a schematic structural diagram of Embodiment 6 of a high-brightness OLED display device of the disclosure.

FIG. 8 is an RGB pixel spectrum diagram of the OLED display devices of Embodiment 3 to Embodiment 6 of the disclosure.

FIG. 9 is a schematic structural diagram of an OLED display device of Comparative Example 1 of the disclosure.

FIG. 10 is an RGB pixel spectrum diagram of the OLED display device of Comparative Example 1 of the disclosure.

FIG. 11 is a schematic structural diagram of an OLED display device of Comparative Example 2 of the disclosure.

FIG. 12 is an RGB pixel spectrum diagram of the OLED display device of Comparative Example 2 of the disclosure.

The marks in the above figures are: 1. Substrate, 2. Anode layer, 21. R-anode, 22. G-anode, 23. B-anode, 3. Organic layer, 31. OLED device unit I, 311. Hole injection layer, 312. Hole transport layer I, 313. Electron blocking layer I, 314. Light emitting layer I, 315. Hole blocking layer I, 316. Electron transport layer I, 32. CGL layer, 33. OLED device unit II, 331. Hole transport layer II, 332. Electron blocking layer II, 333. Light emitting layer II, 334. Hole blocking layer II, 335. Electron transport layer II, 336. Electron injection layer, 4. Cathode layer, 5. CPL layer, 6. Encapsulation layer.

### DETAILED DESCRIPTION

In order to make the purpose, technical solutions and advantages of the embodiments of the disclosure clearer, the technical solutions in the embodiments of the disclosure will be clearly and completely described below in conjunction with the drawings in the embodiments of the disclosure. The following embodiments are used to illustrate the disclosure, but are not used to limit the scope of the disclosure.

In the description of the disclosure, it should be noted that orientations or positional relationships indicated by the terms “upper”, “lower”, “front”, “back”, “left”, “right”, “vertical”, “inner”, “outer”, etc., are based on orientations or positional relationships shown in the figures. It is only for the convenience of describing the disclosure and simplifying the description. It does not indicate or imply that the device or element referred to must have a specific orientation or a construction and operation based on a specific orientation, and therefore should not be construed as limitations of the disclosure.

In the description of the disclosure, it should be noted that, unless otherwise clearly stated and limited, the terms “installation”, “association” and “connection” should be understood in a broad sense. For example, it can be a fixed connection, a detachable connection, or an integral connection; it can be a mechanical connection or an electrical connection; it can be a direct connection or an indirect connection through an intermediate medium. For those of ordinary skill in the art, specific meanings of the above terms in the disclosure can be understood according to specific cases.

In the related art, the current silicon-based OLED full-color products have the following problems: 1) in the W+CF process, a WOLED device cannot independently emit spectrum because RGB light emitting layers emit light at the same time, a CF (Color Filter) needs to be used to achieve RGB independent light emission and color control, which leads to a large light emission loss and a lower light emission efficiency; 2) in the RGB-SBS process, when silicon-based products achieve high brightness, due to the small single pixel opening of an FMM mask, a hole blocking problem may occur after an FMM is evaporated for about ten times, and the product yield is lower. Therefore, in order to solve the above technical problems, the disclosure provides a high-brightness OLED display device, preparation method thereof, and display apparatus.

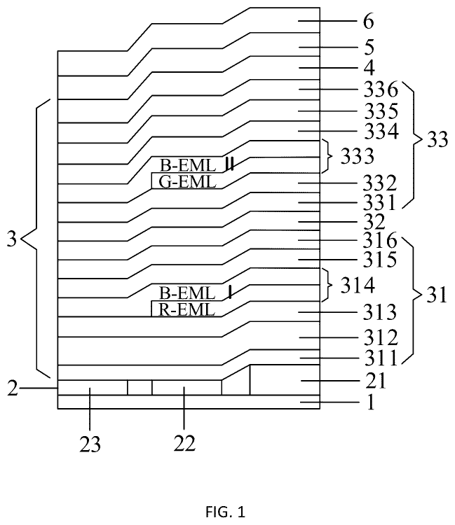

The specific embodiment of the disclosure is: as shown in FIGS. 1 to 7, the disclosure provides a high-brightness OLED display device, including a substrate 1 and an optical microcavity structure on the substrate 1. The optical microcavity structure includes an R optical microcavity area, a G optical microcavity area and a B optical microcavity area. A cavity length of the G optical microcavity area is greater than a cavity length of the B optical microcavity area and smaller than a cavity length of the R optical microcavity area. In the disclosure, optical microcavity areas with different cavity lengths are set at corresponding positions of R, G, and B pixels on the substrate 1, so that R, G, and B pixels in the OLED display device have corresponding microcavity optical paths, and the RGB pixels can independently emit corresponding spectrum without using the CF, realizing color control of silicon-based products and improving light emission efficiency.

Specifically, the optical microcavity structure includes an anode layer 2 with a total reflection function, an organic layer 3 on the anode layer 2, and a cathode layer 4 with a semi-reflective and semi-transparent function. A layer structure of the anode layer 2 includes Ag/ITO (Ag is a total reflection metal), Al/TiN/ITO (Al is a total reflection metal), Al/ITO/MoO₃ (Al is a total reflection metal), Al/Co/MoO₃ (Al is a total reflection metal), Al/Ni/MoO₃ (Al is a total reflection metal), Al/MoO₃ (Al is a total reflection metal). The total reflection metal in the layer structure makes the layer structure have the total reflection function. The cathode layer 4 can be made of Mg:Ag, Yb:Ag, Li:AL, Ga, ITO, IZO and other materials, and reflectivity of the cathode layer 4 is generally adjusted to 20% to 70% through the thickness and ratio of the cathode layer. The anode layer 2 includes an R-anode 21, a G-anode 22 and a B-anode 23. The organic layer 3 includes an organic layer I, an organic layer II and an organic layer III. The cathode layer includes an R-cathode, a G-cathode and a B-cathode with the same thickness. The R optical microcavity area includes the R-anode 21, the organic layer I on the R-anode 21, and the R-cathode. The G optical microcavity area includes the G-anode 22, the organic layer II on the G-anode 22, and the G-cathode. The B optical microcavity area includes the B-anode 23, the organic layer III on the B-anode 23, and the B-cathode. The organic layer I and the organic layer II have the same film structure. A thickness of the R-anode 21 is greater than a thickness of the G-anode 22. A thickness of the G-anode 22 is equal to a thickness of the B-anode 23. A thickness of the organic layer I or a thickness of the organic layer II is greater than a thickness of the organic layer III. Both the organic layer I and the organic layer II are provided with a microcavity thickness compensation layer. The microcavity thickness compensation layer includes an R light emitting layer (R-EML), a G light emitting layer (G-EML), or a combination of the R light emitting layer (R-EML) and G light emitting layer (G-EML). The R light emitting layer (R-EML) and the G light emitting layer (G-EML) are stacked when being combined.

In the disclosure, the thicknesses of the organic layer I, the organic layer II and the organic layer III are adjusted under the action of the microcavity thickness compensation layer by adjusting the thicknesses of the corresponding R-anode 21, G-anode 22 and B-anode 23 on the anode layer 2, so that the thickness of the R-anode 21 is greater than the thickness of the G-anode 22 and the thickness of the B-anode 23, so that the R-anode 21 and the G-anode 22 are covered with the R light emitting layer (R-EML) and/or the G light emitting layer (G-EML), the cavity length of the corresponding optical microcavity area can be adjusted, R, G, and B pixels have corresponding microcavity optical paths, so that RGB pixels can independently emit the corresponding spectrum without using the CF. The R light emitting layer (R-EML) and the G light emitting layer (G-EML) are prepared using the FMM mask, and other film layers are prepared using the CMM mask, so that the openings of the FMM mask are RG pixels, increasing an aperture ratio of the FMM mask and improving service life of the FMM mask. The entire process at most uses two times of the FMM mask to achieve RGB independent light emission, avoiding the hole blocking problem due to evaporating multiple film layer masks, and improving product yield.

Specifically, the cavity length of the R optical microcavity area, the G optical microcavity area or the B optical microcavity area is a sum of thicknesses of respective film layers in the R optical microcavity area, the G optical microcavity area or the B optical microcavity area, correspondingly, and the thickness of each film layer satisfies an OLED microcavity calculation formula of:

$$\sum {n}_{i} {d}_{i} + \frac{∅}{4 Π} λ = m \times \frac{λ}{2} .$$

Here: nᵢ is a refractive index of each film layer, dᵢ is a thickness of each film layer, Ø is a phase shift of light reflection on surfaces of the cathode layer 4 and anode layer 2, γ is a wavelength value at a highest value of a spectrum, m is a positive integer, is an order of the microcavity. The wavelengths of R, G, and B are 620 nm, 525 nm, and 460 nm respectively. Only when the thickness and wavelength of each film layer in the optical microcavity structure meet the above formula can the light be enhanced. When calculating the thickness of each film layer, the phase shift of light reflection on the surfaces of the cathode layer 4 and the anode layer 2 is ignored. Σnᵢ dᵢ in the formula satisfies: Σnᵢ dᵢ=nd, where n is an average refractive index of a corresponding optical microcavity area, and d is a cavity length of the corresponding optical microcavity area.

When thicknesses and refractive indexes of other film layers on the organic layer 3 are known except for the thickness of the R light emitting layer (R-EML) and the thickness of the G light emitting layer (G-EML), and the material of the R light emitting layer (R-EML) and the material of the G light emitting layer (G-EML) are known (that is, the refractive index is known), the thickness of the R light emitting layer (R-EML) and/or the thickness of the G light emitting layer (G-EML) can be calculated according to the above formula. In some embodiments, the cavity length of the B optical microcavity area and the cavity length of the G optical microcavity area can be separately calculated by a formula of

$$nd = m \times \frac{λ}{2} ,$$

a difference between the cavity length of the B optical microcavity area and the cavity length of the G optical microcavity area is a thickness of the microcavity thickness compensation layer. According to the calculation, the thickness of the R light emitting layer (R-EML) and the thickness of the G light emitting layer (G-EML) are both set to 10 to 80 nm. The thickness of the B-anode 23 and the thickness of the G-anode 22 are consistent, and are both set to 5 to 80 nm.

When the thickness of the R light emitting layer (R-EML) and the thickness of the G light emitting layer (G-EML) are calculated, except for the unknown thickness of the R-anode 21, and the thicknesses and refractive indexes of other film layers on the organic layer 3 are known, the thickness of the R-anode 21 is calculated according to the above formula. In some embodiments, the cavity length of the G optical microcavity area and the cavity length of the R optical microcavity area can also be calculated separately by a formula of

$$nd = m \times \frac{λ}{2} .$$

A difference between the cavity lengths of the two optical microcavity areas is a difference between a thickness of the R-anode 21 and a thickness of the G-anode 22, or between a thickness of the R-anode 21 and a thickness of the B-anode 23, and the thickness of the R-anode 21 after calculation is 50 to 200 nm.

Regarding the specific structure of the above high-brightness OLED display device, the disclosure will be explained in detail through the following embodiments.

### Embodiment 1

As shown in FIG. 1, the embodiment in the disclosure provides a high-brightness OLED display device, including a substrate 1 (a driving substrate 1, not shown in the figure). The substrate 1 is provided with an anode layer 2 including an R-anode 21, a G-anode 22 and a B-anode 23. The anode layer 2 is made of ITO or IZO. The thickness of the G-anode 22 is equal to the thickness of the B-anode 23, i.e., 10 nm. The thickness of the R-anode 21 is greater than the thickness of the G-anode 22 and the thickness of B-anode 23, and is 70 nm. An organic layer 3 composed of stacked film layers is provided on the anode layer 2. A cathode layer 4 is provided on the organic layer 3. The cathode layer 4 is connected to an encapsulation layer 6 through a CPL layer 5.

Specifically, a film structure of the organic layer 3 includes an OLED device unit I 31, an OLED device unit II 33 and a CGL layer 32 connected between the OLED device unit I 31 and the OLED device unit II 33. The OLED device unit I 31 is connected to the anode layer 2. The OLED device unit II 33 is connected to the cathode layer 4. Two OLED device units are connected in series through the CGL layer 32 to form the organic layer 3 for light emission.

The OLED device unit I 31 includes a light emitting layer I 314. One side of the light emitting layer I 314 is connected to the anode layer 2 through an electron blocking layer I 313, a hole transport layer I 312, and a hole injection layer 311 in sequence. The other side of the light emitting layer I 314 is connected to the CGL layer 32 through a hole blocking layer I 315 and an electron transport layer I 316. In some embodiments, the OLED device unit I 31 is not limited to the above film layer structure, and other film layer structures can be added or corresponding film layer structures can be reduced as needed. The OLED device unit II 33 includes a light emitting layer II 333. One side of the light emitting layer II 333 is connected to the CGL layer 32 through an electron blocking layer II 332 and a hole transport layer II 331. The other side of the light emitting layer II 333 is connected to the cathode layer 4 through a hole blocking layer II 334, an electron transport layer II 335 and an electron injection layer 336. In some embodiments, the OLED device unit II 33 is not limited to the above film layer structure, and other film layer structures can also be added as needed.

The light emitting layer I 314 includes an R light emitting layer (R-EML) and a B light emitting layer I (B-EML I) arranged in sequence from bottom to top. The R light emitting layer (R-EML) covers the R-anode 21 and the G-anode 22, and the B light emitting layer I (B-EML I) covers the anode layer 2. The R light emitting layer (R-EML) is prepared using red light host materials and red light doping materials with electron transmission properties (such as CBP, TCTA, DFC, TAZ, BCP, OXD7, etc.). The B light emitting layer I (B-EML I) is prepared using blue light host materials and blue light doping materials with electron transmission properties (such as ADN, TBADN, MADN, BDSA, BTSA, etc.). An absolute value of a difference between LUMO energy levels of the host materials of the R light emitting layer (R-EML) and the B light emitting layer I (B-EML I) is less than 0.4 eV, allowing electrons to migrate from the B light emitting layer I (B-EML I) to the R light emitting layer (R-EML). An absolute value of a difference between HOMO energy levels of the host materials of the R light emitting layer (R-EML) and the B light emitting layer I (B-EML I) is greater than 0.4 eV, making it impossible for holes to migrate from the R light emitting layer (R-EML) to the B light emitting layer I (B-EML I).

The light emitting layer II 333 includes a G light emitting layer (G-EML) and a B light emitting layer II (B-EML II) arranged in sequence from bottom to top. The G light emitting layer (G-EML) covers the R-anode 21 and the G-anode. 22. The B light emitting layer II (B-EML II) covers the anode layer 2. The G light emitting layer (G-EML) is prepared using bipolar green light host materials and green light doping materials (such as CBP, TCTA, DFC, TAZ, BCP, OXD7, etc.). The B light emitting layer II (B-EML II) is prepared using blue light host materials and blue light doping materials with electron transport properties. An absolute value of a difference between LUMO energy levels of the host materials of the G light emitting layer (G-EML) and the B light emitting layer II (B-EML II) is less than 0.4 eV, allowing electrons to migrate from the B light emitting layer II (B-EML II) to the G light emitting layer (G-EML). An absolute value of a difference between HOMO energy levels of the host materials of the G light emitting layer (G-EML) and the B light emitting layer II (B-EML II) is greater than 0.4 eV, making it impossible for holes to migrate from the G light emitting layer (G-EML) to the B light emitting layer II (B-EML II).

The thickness of the R light emitting layer (R-EML) and the thickness of the G light emitting layer (G-EML) can be calculated according to the OLED microcavity calculation formula, and both of the thickness of the R light emitting layer (R-EML) and the thickness of the G light emitting layer (G-EML) are set to 30 nm. The R light emitting layer (R-EML) and the G light emitting layer (G-EML) are all prepared using FMM masks, and the openings are RG pixels, so that the R light emitting layer (R-EML) and G light emitting layer (G-EML) can be evaporated onto the R-anode 21 and the G-anode 22 respectively, increasing the aperture ratio of the FMM mask and improving the service life of the FMM mask. The entire process only uses two times of the FMM mask to achieve RGB independent light emission, avoiding the hole blocking problem due to evaporating multiple film layer masks, and improving product yield. Moreover, light emitting layers on the OLED device unit I 31 and the OLED device unit II 33 both include the B light emitting layer, which increases light emission efficiency of blue light.

The preparation method of the above-mentioned high-brightness OLED display device includes the following steps.

Step 1: preparing an anode layer 2 including an R-anode 21, a G-anode 22 and a B-anode 23 on the substrate 1, where a thickness of the R-anode 21 is greater than a thickness of the G-anode 22 and a thickness of the B-anode 23.

Step 2: stacking and preparing an organic layer 3 on the anode layer 2, including preparing a B light emitting layer covering the anode layer 2 using a CMM mask and preparing an R light emitting layer (R-EML) and/or a G light emitting layer (G-EML) covering the R-anode 21 and the G-anode 22 using an FMM mask.

Specifically, 1) the OLED device unit I 31 is prepared by:
\hat{1} using a CMM mask to sequentially prepare the hole injection layer 311, the hole transport layer I 312, and the electron blocking layer I 313 on the anode layer 2;
\hat{2} using an FMM mask to prepare the R light emitting layer (R-EML) with a thickness of 30 nm on the electron blocking layer I 313, where openings of the FMM mask are RG pixels, and the R light emitting layer (R-EML) can be directly evaporated above the R-anode 21 and the G-anode 22;
\hat{3} using a CMM mask to sequentially prepare the B light emitting layer I (B-EML I), the hole blocking layer I 315, and the electron transport layer I 316 on the electron blocking layer I 313 and the R light emitting layer (R-EML). The B light emitting layer I (B-EML I) adopts the host material of electron transport type material, so that electrons can be transmitted to the R light emitting layer (R-EML).

2) The CGL layer 32 is prepared by: using a CMM mask to prepare the CGL layer 32 on the electron transport layer I 316.

3) The OLED device unit II 33 is prepared by:
\hat{1} using a CMM mask to sequentially prepare the hole transport layer II 331 and the electron blocking layer II 332 on the CGL layer 32;
\hat{2} using an FMM mask to prepare the G light emitting layer (G-EML) with a thickness of 30 nm on the electron blocking layer II 332, where openings of the FMM mask are RG pixels, and the G light emitting layer (G-EML) can be directly evaporated above the R-anode 21 and the G-anode 22;
\hat{3} using a CMM mask to sequentially prepare the B light emitting layer II (B-EML II), the hole blocking layer II 334, and the electron injection layer 336 on the electron blocking layer II 332 and the G light emitting layer (G-EML). The B light emitting layer II (B-EML II) adopts the host material of electron transport type material, so that electrons can be transmitted to the G light emitting layer (G-EML).

Step 3: preparing a cathode layer 4, a CPL layer 5 and an encapsulation layer 6 on the organic layer 3 in sequence.

### Embodiment 2

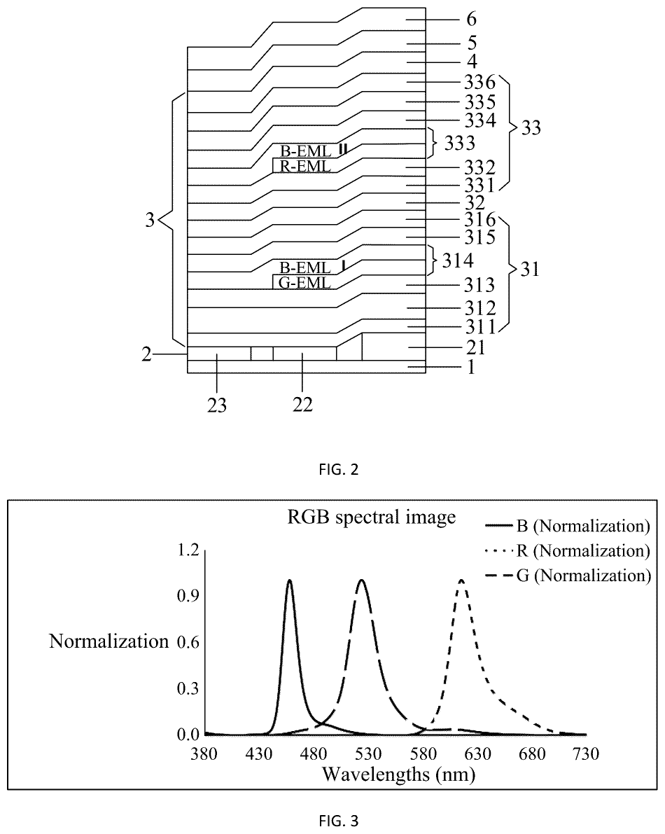

As shown in FIG. 2, the embodiment in the disclosure provides a high-brightness OLED display device. Structures of the light emitting layer I 314 and the light emitting layer II 333 are different from the structures of the light emitting layer I 314 and the light emitting layer II 333 in Embodiment 1. The light emitting layer I 314 and the light emitting layer II 333 in Embodiment 1 are exchanged, that is, the light emitting layer I 314 includes a G light emitting layer (G-EML) and a B light emitting layer I (B-EML I) arranged in sequence from bottom to top. The G light emitting layer (G-EML) covers the R-anode 21 and the G-anode 22. The B light emitting layer I (B-EML I) covers the anode layer 2. The light emitting layer II 333 includes an R light emitting layer (R-EML) and a B light emitting layer II (B-EML II) arranged in sequence from bottom to top. The R light emitting layer (R-EML) covers the R-anode 21 and the G-anode 22. The B light emitting layer II (B-EML II) covers the anode layer 2.

The preparation method of the high-brightness OLED display device is specifically adjusted according to the structural adjustment of the light emitting layer I 314 and the light emitting layer II 333, and will not be repeated here.

The RGB pixel spectrum of the high-brightness OLED display devices obtained in Embodiment 1 and Embodiment 2 is shown in FIG. 3. It can be seen that the spectrum includes three discrete bands, namely a blue light band, a green light band and a red light band. The blue light band reaches its peak at a wavelength of 460 nm, the green light band reaches its peak at a wavelength of 525 nm, and the red light band reaches its peak at a wavelength of 620 nm. There are fewer impurity peaks at wavelengths other than the peak, achieving the purpose of RGB independent emission spectrum.

The optical performance parameters of the above high-brightness OLED display devices are shown in Table 1.

TABLE 1
Optical performance parameters of OLED display
devices in Embodiment 1 and Embodiment 2

| B | | | | | | G | | | |
|---|---|---|---|---|---|---|---|---|---|
| Voltage | Eff | | | | | Voltage | Eff | | |
| V | cd/A | CIEx | CIEy | Peak | FWHM | V | cd/A | CIEx | CIEy |
| 7.39 | 8.51 | 0.1388 | 0.0512 | 460 | 15.2 | 7.74 | 92 | 0.2318 | 0.6983 |
| | | | R | | | | | | DCI-P3 |
| | G | | Voltage | Eff | | | | | color |
| | Peak | FWHM | V | cd/A | CIEx | CIEy | Peak | FWHM | gamut |
| | 527 | 32.2 | 7.90 | 41.3 | 0.6556 | 0.3427 | 607 | 29 | 101.10 |

It can be seen from the above table that when CF is not used, a DCI-P3 color gamut of the display device of the disclosure is greater than 100%, which meets product requirements.

### Embodiment 3

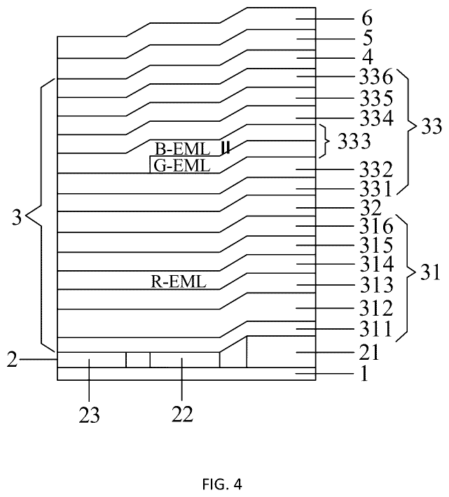

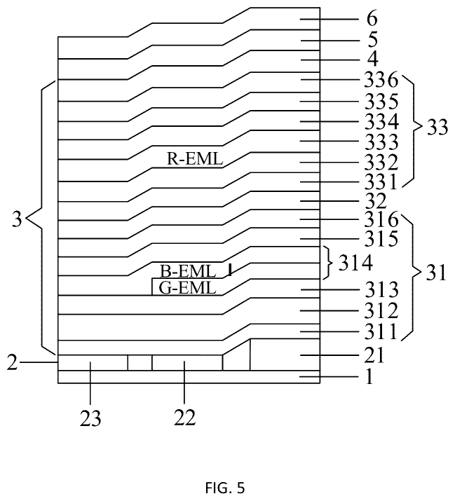

As shown in FIG. 4, the embodiment in the disclosure provides a high-brightness OLED display device. The difference from Embodiment 1 is that the structure of the light emitting layer I 314 is different. The light emitting layer I 314 includes an R light emitting layer (R-EML) covering an anode layer 2. The structure of the light emitting layer II 333 is the same as the structure of the light emitting layer II 333 in Embodiment 1. The light emitting layer II 333 includes a G light emitting layer (G-EML) and a B light emitting layer II (B-EML II) arranged in sequence from bottom to top. The G light emitting layer (G-EML) covers the R-anode 21 and the G-anode 22. The B light emitting layer II (B-EML II) covers the anode layer 2. The thickness of the R light emitting layer (R-EML) is 30 nm, the thickness of the G light emitting layer (G-EML) is 55 nm, and the thickness of the R-anode 21 is 70 nm. The thicknesses of other film layer structures are the same as the thicknesses of the corresponding film layers in Embodiment 1.

A method for preparing the OLED device unit I 31 in the preparation method of the high-brightness OLED display device in this embodiment is different from the method for preparing the OLED device unit I 31 in Embodiment 1. The OLED device unit I 31 in this embodiment is prepared by:
\hat{1} using a CMM mask to sequentially prepare the hole injection layer 311, the hole transport layer I 312, and the electron blocking layer I 313 on the anode layer 2;
\hat{2} using a CMM mask to prepare the R light emitting layer (R-EML) with a thickness of 30 nm on the entire surface of the electron blocking layer I 313;
\hat{3} using a CMM mask to sequentially prepare the B light emitting layer I (B-EML I), the hole blocking layer I 315, and the electron transport layer I 316 on the R light emitting layer (R-EML), where the B light emitting layer I (B-EML I) adopts the host material of electron transport type material, so that electrons can be transmitted to the R light emitting layer (R-EML).

### Embodiment 4

As shown in FIG. 5, the embodiment in the disclosure provides a high-brightness OLED display device. The difference from Embodiment 3 is that the structures of the light emitting layer I 314 and the light emitting layer II 333 in Embodiment 3 are exchanged, that is, the light emitting layer I 314 includes a G light emitting layer (G-EML) and a B light emitting layer I (B-EML I) arranged in sequence from bottom to top. The G light emitting layer (G-EML) covers the R-anode 21 and the G-anode 22. The B light emitting layer I (B-EML I) covers the anode layer 2. The light emitting layer II 333 includes the R light emitting layer (R-EML) covering the anode layer 2. The preparation method of the high-brightness OLED display device is specifically adjusted according to the structural adjustment of the light emitting layer I 314 and the light emitting layer II 333, and will not be repeated here.

### Embodiment 5

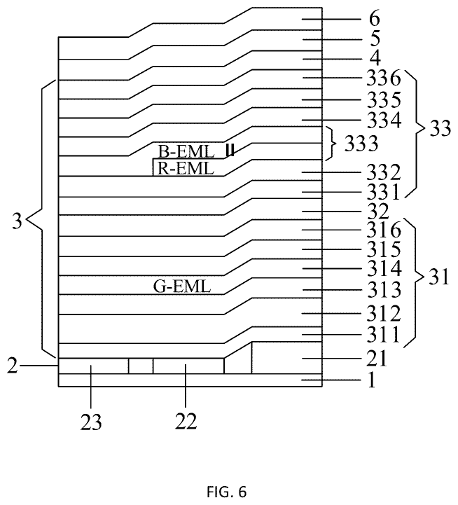

As shown in FIG. 6, the embodiment in the disclosure provides a high-brightness OLED display device. The difference from Embodiment 2 is that the structure of the light emitting layer I 314 is different, that is, the light emitting layer I 314 includes a G light emitting layer (G-EML) covering an anode layer 2, where the light emitting layer II 333 has the same structure as that of Embodiment 2. The light emitting layer II 333 includes the R light emitting layer (R-EML) and the B light emitting layer II (B-EML II) arranged in sequence from bottom to top. The R light emitting layer (R-EML) covers the R-anode 21 and the G-anode 22. The B light emitting layer II (B-EML II) covers the anode layer 2. The thickness of the R light emitting layer (R-EML) is 55 nm, and the thickness of the G light emitting layer (G-EML) is 30 nm. The thicknesses of the other film layers are the same as the thicknesses of the corresponding film layers in Embodiment 3.

A method for preparing the OLED device unit I 31 in the preparation method of the high-brightness OLED display device in this embodiment is different from the method for preparing the OLED device unit I 31 in Embodiment 2. The OLED device unit I 31 in this embodiment is prepared by:
\hat{1} using a CMM mask to sequentially prepare the hole injection layer 311, the hole transport layer I 312, and the electron blocking layer I 313 on the anode layer 2;
\hat{2} using a CMM mask to prepare the G light emitting layer (G-EML) with a thickness of 30 nm on the entire surface of the electron blocking layer I 313;
\hat{3} using a CMM mask to sequentially prepare the hole blocking layer I 315 and the electron transport layer I 316 on the G light emitting layer (G-EML).

### Embodiment 6

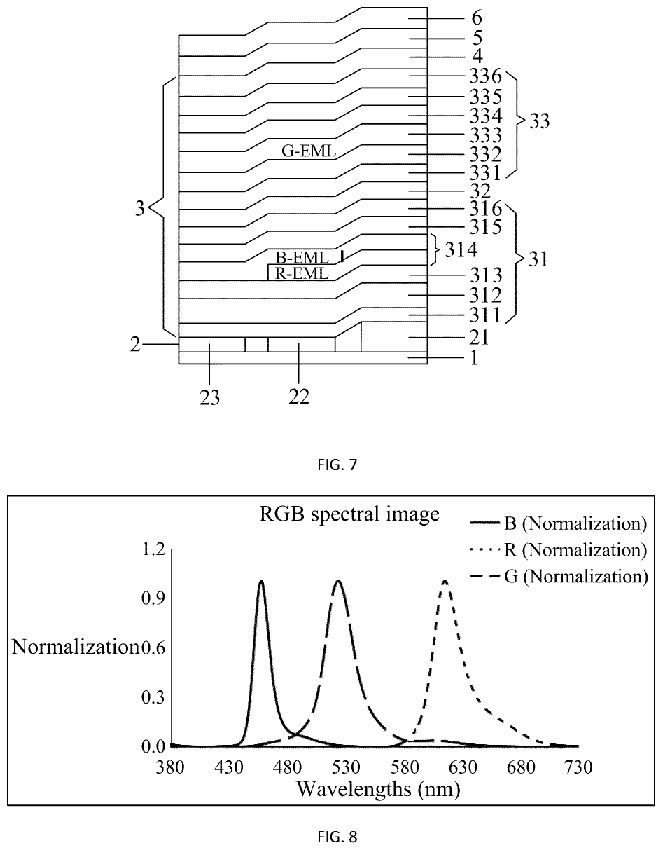

As shown in FIG. 7, the embodiment in the disclosure provides a high-brightness OLED display device. The difference from Embodiment 5 is that the structures of the light emitting layer I 314 and the light emitting layer II 333 in Embodiment 5 are exchanged, that is, the light emitting layer I 314 includes an R light emitting layer (R-EML) and a B light emitting layer I (B-EML I) arranged in sequence from bottom to top. The R light emitting layer (R-EML) covers the R-anode 21 and G-anode 22. The B light emitting layer I (B-EML I) covers the anode layer 2. The light emitting layer II 333 includes the G light emitting layer (G-EML) covering the anode layer 2.

The preparation method of the high-brightness OLED display device is specifically adjusted according to the structural adjustment of the light emitting layer I 314 and the light emitting layer II 333, and will not be repeated here.

The RGB pixel spectrum of the high-brightness OLED display devices obtained in the above Embodiments 3 to 6 is shown in FIG. 8. It can be seen that the spectrum includes three discrete bands, namely, a blue light band, a green light band and a red light band. The blue light band reaches its peak at a wavelength of 460 nm, the green light band reaches its peak at a wavelength of 530 nm, and the red light band reaches its peak at a wavelength of 620 nm. There are fewer impurity peaks at wavelengths other than the peak, achieving the purpose of RGB independent emission spectrum.

The optical performance parameters of the above high-brightness OLED display devices are shown in Table 2.

TABLE 2
Optical performance parameters of the OLED
display devices of Embodiments 3 to 6

| B | | | | | | G | | | |
|---|---|---|---|---|---|---|---|---|---|
| Voltage | Eff | | | | | Voltage | Eff | | |
| V | cd/A | CIEx | CIEy | Peak | FWHM | V | cd/A | CIEx | CIEy |
| 6.42 | 7.1 | 0.1433 | 0.0631 | 460 | 15.3 | 6.47 | 88.4 | 0.2042 | 0.6926 |
| | | | R | | | | | | DCI-P3 |
| | G | | Voltage | Eff | | | | | color |
| | Peak | FWHM | V | cd/A | CIEx | CIEy | Peak | FWHM | gamut |
| | 524 | 28.9 | 6.57 | 40.2 | 0.6540 | 0.3440 | 607 | 26.3 | 100.10 |

It can be seen from the above table that when CF is not used, the DCI-P3 color gamut of the display device of the disclosure is greater than 100%, which meets product requirements.

### Embodiment 7

The embodiment of the disclosure provides a high-brightness OLED display apparatus, including the OLED display device according to any one of Embodiments 1 to 6.

The display apparatus can be: a liquid crystal panel, a monitor, a television, a digital photo frame, a navigator, a computer, a collection, a car display, a camera and other products with display functions, and are used in the field of optical display.

### Comparative Example 1

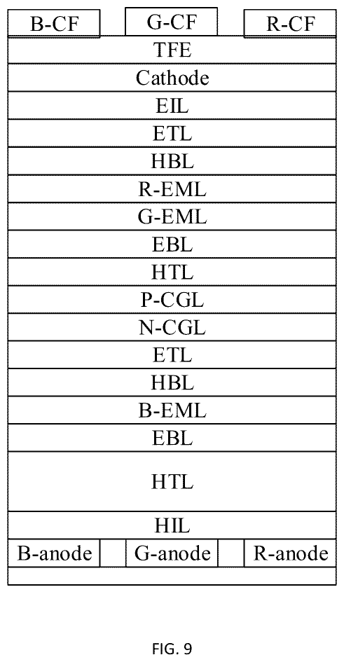

The comparative example provides an OLED display device, which is a WOLED (white light OLED) plus a CF (color filter). The structure is shown in FIG. 9. A substrate, an anode layer, a hole injection layer (HIL), a hole transport layer (HTL), an electron blocking layer (EBL), a B light emitting layer (B-EML), a hole blocking layer (HBL), an electron transport layer (ETL), a charge generation layer (N-CGL and P-CGL), a hole transport layer (HTL), an electron blocking layer (EBL), a G light emitting layer (G-EML), an R light emitting layer (R-EML), a hole blocking layer (HBL), an electron transport layer (ETL), an electron injection layer (EIL), a cathode (Cathode) layer, an encapsulation layer (TFE) and a CF layer are stacked in sequence from bottom to top. A capping layer (CPL) (not shown in the figure) is provided between the cathode layer and the encapsulation layer (TFE). The thickness of the R-anode, the thickness of the G-anode, and the thickness of the B-anode on the anode layer are equal to the thickness of the G-anode and the thickness of the B-anode in Embodiment 1. The difference between the organic layer and Embodiment 1 is that both the R light emitting layer (R-EML) and the G light emitting layer (G-EML) are evaporated on the entire surface, and a CF layer is provided on the encapsulation layer, where the thickness of each film layer of the organic layer 3 is equal to the thickness of the corresponding film layer in Embodiment 1.

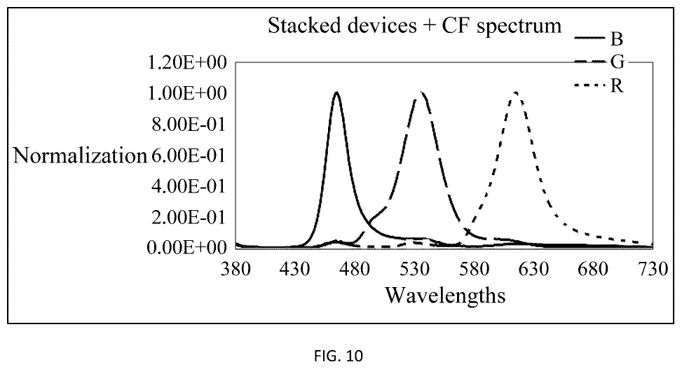

The RGB pixel spectrum of the OLED display device is shown in FIG. 10. It can be seen that the spectrum includes three discrete bands, namely a blue light band, a green light band and a red light band. The blue light band reaches its peak at a wavelength of 460 nm, the green light band reaches its peak at a wavelength of 530 nm, and the red light band reaches its peak at a wavelength of 620 nm. Moreover, there are more impurity peaks at wavelengths other than the peak, resulting in a larger light emission loss and lower light emission efficiency.

### Comparative Example 2

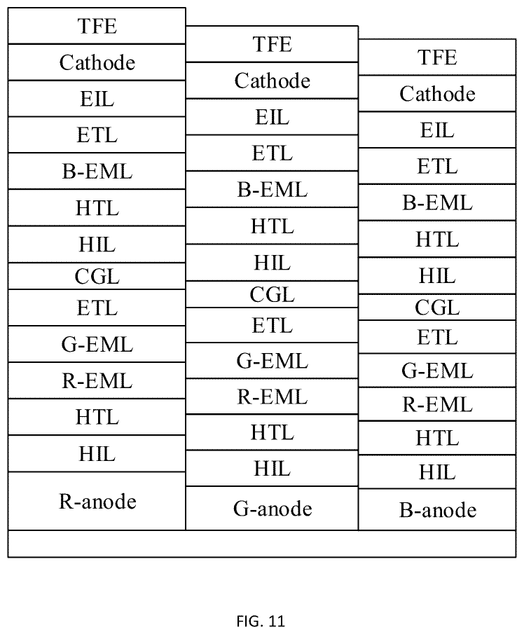

The comparative example provides an OLED display device, the structure of which is shown in FIG. 11. A substrate, an anode layer, a hole injection layer (HIL), a hole transport layer (HTL), an R light emitting layer (R-EML), a G light emitting layer (G-EML), an electron transport layer (ETL), a charge generation layer (CGL), a hole injection layer (HIL), a hole transport layer (HTL), a B light emitting layer (B-EML), an electron transport layer (ETL), an electron injection layer (EIL), a cathode (Cathode) layer, and an encapsulation layer (TFE) are stacked in sequence from bottom to top. A capping layer (CPL) (not shown in the figure) is set between the cathode layer (Cathode) and the encapsulation layer (TFE). The thickness of each film layer in the organic layer between the anode layer and the cathode layer is equal to the thickness of the corresponding film layer in Embodiment 1. The thickness of the G-anode on the anode layer is greater than the thickness of the B-anode and smaller than the thickness of the R-anode. The thickness of the R-anode is 120 nm, the thickness of the G-anode is 70 nm, and the thickness of the B-anode is 10 nm. The light modulation effect is achieved by adjusting the cavity length of the microcavity by changing the thickness of the anode corresponding to each pixel.

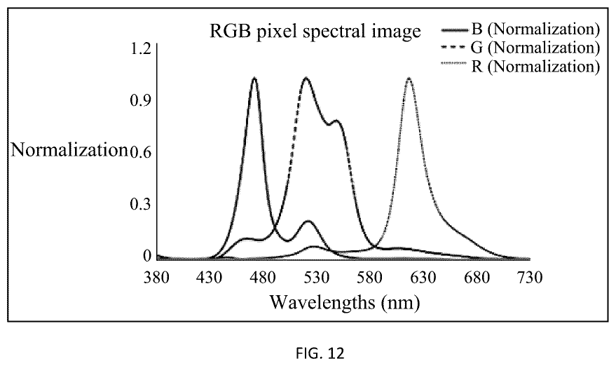

The RGB pixel spectrum of the OLED display device is shown in FIG. 12. It can be seen that the spectrum includes three discrete bands, namely a blue light band, a green light band and a red light band. The blue light band reaches its peak at a wavelength of 460 nm, the green light band reaches its peak at a wavelength of 530 nm, and the red light band reaches its peak at a wavelength of 620 nm. Moreover, there are more impurity peaks at wavelengths other than the peak, resulting in a larger light emission loss and lower light emission efficiency. An additional CF layer must be used to weaken the impurity peaks.

Here, the optical performance parameters of the OLED display devices of Comparative Example 1 and Comparative Example 2 are shown in Table 3.

TABLE 3
Optical performance parameters of the OLED display devices
of Comparative Example 1 and Comparative Example 2

| | R | | | | G | | | | B | | | |
|---|---|---|---|---|---|---|---|---|---|---|---|---|
| Embodiment | Peak | CIEx | CIEy | Eff | Peak | CIEx | CIEy | Eff | Peak | CIEx | CIEy | Eff |
| 1 | 616 | 0.6505 | 0.3302 | 8.4 | 530 | 0.1855 | 0.7517 | 28.7 | 460 | 0.1412 | 0.0425 | 1.5 |
| 2 | 616 | 0.507 | 0.312 | 23.06 | 530 | 0.253 | 0.693 | 47.94 | 460 | 0.141 | 0.065 | 3.04 |

Compared the optical performance parameters of the OLED display devices of Comparative Examples 1 and 2 with that of the OLED display devices of Embodiments 1 to 6, the light emission efficiency of each pixel of the OLED display devices of Embodiments 1 to 6 (the larger the eff value is, the higher the luminous efficiency is) is significantly higher than Comparative Example 1 and Comparative Example 2, and the product of the disclosure can achieve higher brightness.

Therefore, this Comparative example only adjusts the cavity length of the microcavity for light modulation by changing the thickness of the corresponding pixels on the anode layer, so that the obtained RGB pixel spectrum has many impurity peaks at wavelengths other than the peak, resulting in a larger light emission loss and lower light emission efficiency. In Embodiments 1 to 6 of the disclosure, the cavity length of the microcavity is adjusted by simultaneously changing the thickness of the anode layer and the thickness of the light emitting layer to perform light modulation, so that the light emitting layer of the corresponding pixel emits light, while light emitting layers of other pixels do not emit light, thus the obtained RGB pixel spectrum has fewer impurity peaks at wavelengths other than the peak, there is no need to use an additional CF layer to weaken the impurity peaks, and high color gamut and high brightness can be obtained.

The above description only illustrates some principles of the disclosure. This description is not intended to limit the disclosure to the specific structure and scope of application shown. Therefore, all corresponding modifications and equivalents that may be utilized belongs to the scope of the disclosure.

What is claimed is:

1. A high-brightness organic light emitting diode (OLED) display device, comprising:
a substrate; and
an optical microcavity structure on the substrate;
wherein the optical microcavity structure comprises an R optical microcavity area, a G optical microcavity area and a B optical microcavity area, and a cavity length of the G optical microcavity area is greater than a cavity length of the B optical microcavity area and smaller than a cavity length of the R optical microcavity area.

2. The high-brightness OLED display device according to claim 1, wherein the optical microcavity structure comprises:
an anode layer with a total reflection function,
an organic layer on the anode layer, and
a cathode layer with a semi-reflective and semi-transparent function.

3. The high-brightness OLED display device according to claim 2, wherein
the anode layer comprises an R-anode, a G-anode and a B-anode, the organic layer comprises an organic layer I, an organic layer II and an organic layer III, and the cathode layer comprises an R-cathode, a G-cathode and a B-cathode; and
the R optical microcavity area comprises the R-anode, the organic layer I on the R-anode, and the R-cathode, the G optical microcavity area comprises the G-anode, the organic layer II on the G-anode, and the G-cathode, and the B optical microcavity area comprises the B-anode, the organic layer III on the B-anode, and the B-cathode.

4. The high-brightness OLED display device according to claim 3, wherein the cavity length of the R optical microcavity area is a sum of thicknesses of respective film layers in the R optical microcavity area, the cavity length of the G optical microcavity area is a sum of thicknesses of respective film layers in the G optical microcavity area, the cavity length of the B optical microcavity area is a sum of thicknesses of respective film layers in the B optical microcavity area, and the thickness of each film layer satisfies a formula of:
$$\sum {n}_{i} {d}_{i} + \frac{∅}{4 Π} λ = m \times \frac{λ}{2} ;$$
wherein nᵢ is a refractive index of each film layer, dᵢ is a thickness of each film layer, Ø is a phase shift of light reflection on surfaces of the cathode layer and anode layer, γ is a wavelength value at a highest value of a spectrum, m is a positive integer and is an order of a microcavity.

5. The high-brightness OLED display device according to claim 3, wherein
the organic layer I and the organic layer II have the same structure, and
a thickness of the R-anode is greater than a thickness of the G-anode.

6. The high-brightness OLED display device according to claim 3, wherein
a thickness of the G-anode is equal to a thickness of the B-anode, and
a thickness of the organic layer I or a thickness of the organic layer II is greater than a thickness of the organic layer III.

7. The high-brightness OLED display device according to claim 6, wherein
a microcavity thickness compensation layer is provided in both the organic layer I and the organic layer II, and the microcavity thickness compensation layer comprises an R light emitting layer and/or a G light emitting layer, and
a thickness of the R light emitting layer and a thickness of the G light emitting layer are set to a range of 10 nm to 80 nm.

8. The high-brightness OLED display device according to claim 6, wherein
the thickness of the B-anode and the thickness of the G-anode are set to a range of 5 nm to 80 nm, and
a thickness of the R-anode is set to a range of 50 nm to 200 nm.

9. The high-brightness OLED display device according to claim 3, wherein
the organic layer comprises an OLED device unit I, OLED device unit II and a charge generation layer (CGL) connected between the OLED device unit I and OLED device unit II,
the OLED device unit I is connected to the anode layer, and
the OLED device unit II is connected to the cathode layer.

10. The high-brightness OLED display device according to claim 9, wherein
the OLED device unit I comprises a light emitting layer I, and one side of the light emitting layer I is connected to the anode layer through an electron blocking layer I, a hole transport layer I and a hole injection layer in sequence, and the other side of the light emitting layer I is connected to the CGL layer through a hole blocking layer I and an electron transport layer I in sequence;
the OLED device unit II comprises a light emitting layer II, and one side of the light emitting layer II is connected to the CGL layer through an electron blocking layer II and a hole transport layer II in sequence, and the other side of the light emitting layer II is connected to the cathode layer through a hole blocking layer II, an electron transport layer II, and an electron injection layer in sequence.

11. The high-brightness OLED display device according to claim 10, wherein
the light emitting layer I comprises an R light emitting layer and a B light emitting layer I arranged in sequence from bottom to top, the R light emitting layer covers the R-anode and the G-anode, and the B light emitting layer I covers the anode layer;
the light emitting layer II comprises a G light emitting layer and a B light emitting layer II arranged in sequence from bottom to top, the G light emitting layer covers the R-anode and the G-anode, and the B light emitting layer II covers the anode layer.

12. The high-brightness OLED display device according to claim 10, wherein
the light emitting layer I comprises a G light emitting layer and a B light emitting layer I arranged in sequence from bottom to top, the G light emitting layer covers the R-anode and the G-anode, and the B light emitting layer I covers the anode layer;
the light emitting layer II comprises an R light emitting layer and a B light emitting layer II arranged in sequence from bottom to top, the R light emitting layer covers the R-anode and the G-anode, and the B light emitting layer II covers the anode layer.

13. The high-brightness OLED display device according to claim 10, wherein
the light emitting layer I comprises an R light emitting layer covering the anode layer, the light emitting layer II comprises a G light emitting layer and a B light emitting layer II arranged in sequence from bottom to top, the G light emitting layer covers the R-anode and the G-anode, and the B light emitting layer II covers the anode layer.

14. The high-brightness OLED display device according to claim 10, wherein
the light emitting layer I comprises a G light emitting layer covering the anode layer, the light emitting layer II comprises an R light emitting layer and a B light emitting layer II arranged in sequence from bottom to top, the R light emitting layer covers the R-anode and the G-anode, and the B light emitting layer II covers the anode layer.

15. The high-brightness OLED display device according to claim 10, wherein
the light emitting layer I comprises a G light emitting layer and a B light emitting layer I arranged in sequence from bottom to top, the G light emitting layer covers the R-anode and the G-anode, and the B light emitting layer I covers the anode layer;
the light emitting layer II comprises an R light emitting layer covering the anode layer.

16. The high-brightness OLED display device according to claim 10, wherein
the light emitting layer I comprises an R light emitting layer and a B light emitting layer I arranged in sequence from bottom to top, the R light emitting layer covers the R-anode and the G-anode, and the B light emitting layer I covers the anode layer;
the light emitting layer II comprises a G light emitting layer covering the anode layer.

17. The high-brightness OLED display device according to claim 1, wherein
the optical microcavity structure is connected to an encapsulation layer through a capping layer (CPL).

18. A high-brightness OLED display apparatus, comprising a high-brightness organic light emitting diode (OLED) display device, wherein the high-brightness OLED display device comprises:
a substrate; and
an optical microcavity structure on the substrate;
wherein the optical microcavity structure comprises an R optical microcavity area, a G optical microcavity area and a B optical microcavity area, and a cavity length of the G optical microcavity area is greater than a cavity length of the B optical microcavity area and smaller than a cavity length of the R optical microcavity area.

19. A method for preparing the high-brightness organic light emitting diode (OLED) display device according to claim 1, comprising:
step 1: preparing an anode layer comprising an R-anode, a G-anode and a B-anode on the substrate, wherein a thickness of the R-anode is greater than a thickness of the G-anode and a thickness of the B-anode;
step 2: stacking and preparing an organic layer on the anode layer, comprising preparing a B light emitting layer covering the anode layer using a common metal mask (CMM) and preparing an R light emitting layer and/or a G light emitting layer covering the R-anode and the G-anode using a fine metal mask (FMM);
step 3: preparing a cathode layer, a capping layer (CPL) and an encapsulation layer on the organic layer in sequence.
